(19) United States
(12) Patent Application Publication
(10) Pub. No.: US 2011/0136285 A1
(43) Pub. Date: Jun. 9, 2011

(54) METHOD FOR MANUFACTURING STACKED FILM AND SOLAR CELL

(75) Inventor: Hyoeng-Ki KIM, Suwon-si (KR)

(73) Assignee: SAMSUNG ELECTRONICS CO., LTD., Suwon-si (KR)

(21) Appl. No.: 12/779,478

(22) Filed: May 13, 2010

(30) Foreign Application Priority Data
Dec. 3, 2009 (KR) 10-2009-0119369

(51) Int. Cl. H01L 21/22; H01L 31/18

(52) U.S. Cl. 438/57; 438/542; 257/E21.135; 257/E21.24

(57) ABSTRACT

A method of manufacturing a stacked film includes; subjecting a semiconductor substrate to a radical oxidation reaction to form a radical oxide layer on a surface of the semiconductor substrate, annealing the radical oxide layer in a hydrogen atmosphere to convert the radical oxide layer to a first passivation layer, and disposing a second passivation layer on the first passivation layer.

This application claims priority to Korean Patent Application No. 10-2009-0119369, filed on Dec. 3, 2009, and all the benefits accruing therefrom under 35 U.S.C. §119, the content of which in its entirety is herein incorporated by reference.

### BACKGROUND OF THE INVENTION

1. Field of the Invention

This disclosure relates to a method of manufacturing a stacked film, and a method of manufacturing a solar cell using the same.

2. Description of the Related Art

A photoelectric conversion device that converts solar energy into electrical energy is currently being extensively researched as a renewable and non-polluting next generation energy source.

If a photoelectric conversion device absorbs solar energy in a photoactive layer, electron-hole pairs (“EHP”) are produced in a semiconductor, and the produced electrons and holes respectively move to an n-type semiconductor and a p-type semiconductor and are collected at the electrode, and thus can be used as electrical energy.

The typical photoelectric conversion device is prepared by forming a dielectric layer on a silicon substrate and then forming an electrode thereon. The dielectric layer is typically an oxide layer or a nitride layer formed by a common chemical vapor deposition (“CVD”) process on a silicon substrate. However, when the oxide layer or nitride layer is formed by such a CVD process, oxygen atoms or silicon atoms that do not participate in normal covalent bonds between oxygen atoms and silicon atoms may exist within the oxide or nitride layer. For example, various defects such as weak Si—Si bonding, strained Si—O bonding, Si dangling bonding, etc. may exist within the interface between the oxide layer or nitride layer and the silicon layer. Such defects may deteriorate electrical operation characteristics of the resulting device and adversely affect electrical productivity thereof.

### BRIEF SUMMARY OF THE INVENTION

One aspect of this disclosure provides a method of manufacturing a stacked film that can improve electrical operation characteristics of a solar cell.

Another aspect of this disclosure provides a method of manufacturing a solar cell using the stacked film.

According to one aspect of this disclosure, an exemplary embodiment of a method of manufacturing a stacked film is provided that includes; subjecting a semiconductor substrate to a radical oxidation reaction to form a radical oxide layer on a surface of the semiconductor substrate, annealing the radical oxide layer in a hydrogen atmosphere to convert the radical oxide layer to a first passivation layer, and disposing a second passivation layer on the first passivation layer.

In one exemplary embodiment, before the step of forming the radical oxide layer, at least one of a doping process wherein an impurity of a different semiconductor type from the semiconductor substrate is doped in the semiconductor substrate and a process of surface texturing the semiconductor substrate may be conducted.

In one exemplary embodiment, the annealing process may be conducted for about 15 minutes to about 25 minutes, at a temperature from about 400° C. to about 1000° C.

According to another aspect of this disclosure, an exemplary embodiment of a method of manufacturing a stacked film is provided that includes; disposing a second passivation layer on a semiconductor substrate, subjecting the semiconductor substrate on which the second passivation layer is disposed to a radical oxidation reaction to form a radical oxide layer between the second passivation layer and the semiconductor substrate, and annealing the radical oxide layer in a hydrogen atmosphere to convert the radical oxide layer to a first passivation layer.

In one exemplary embodiment, before the step of forming the second passivation layer, at least one of a doping process wherein an impurity of a different semiconductor type from the semiconductor substrate is doped in the semiconductor substrate and a process of surface texturing the semiconductor substrate may be conducted.

In one exemplary embodiment, the annealing process may be conducted for about 15 minutes to about 25 minutes, at a temperature from about 400° C. to about 1000° C.

According to still another aspect of this disclosure, an exemplary embodiment of a method of manufacturing a stacked film is provided that includes; subjecting a semiconductor substrate to a radical oxidation reaction to form a radical oxide layer on the surface of the semiconductor substrate, annealing the radical oxide layer in a hydrogen atmosphere to convert the radical oxide layer to a first passivation layer; and removing the first passivation layer formed on the surface of the semiconductor substrate and then disposing a second passivation layer on the semiconductor substrate.

In one exemplary embodiment, before the step of forming the radical oxide layer, at least one of a doping process wherein an impurity of a different semiconductor type from the semiconductor substrate and a process of surface texturing the semiconductor substrate may be conducted.

In one exemplary embodiment, before forming the second passivation layer on the surface of the semiconductor substrate from which the first passivation layer is removed, a doping process wherein an impurity of a different semiconductor type from the semiconductor substrate may be further conducted.

In one exemplary embodiment, the annealing process may be conducted for about 30 minutes or more, at a temperature of from about 400° C. to about 1000° C. In one exemplary embodiment, the semiconductor substrate may be p-type semiconductor, and the impurity may be n-type semiconductor.

In one exemplary embodiment, the radical oxidation reaction may be conducted by at least one of heat oxidation and plasma oxidation.

In one exemplary embodiment, the second passivation layer may be at least one of an oxide layer and a nitride layer.

In one exemplary embodiment, before or after conducting the annealing process, a clean oxidation process may be further conducted.

An exemplary embodiment of a method of manufacturing a solar cell is provided that includes; providing a semiconductor substrate including a first semiconductor layer including a first type of semiconductor and a second semiconductor layer including a second type of semiconductor, and a stacked film including a first passivation layer and a second passivation layer positioned on the semiconductor substrate or a second passivation layer positioned on the semiconductor substrate; and disposing a first electrode electrically connected with the first type of impurity containing semiconductor layer, and a second electrode electrically connected with the second type of impurity containing semiconductor layer.

In one exemplary embodiment, the first semiconductor layer may be a p-type semiconductor layer, and the second semiconductor layer may be an n-type semiconductor layer.

Since the stacked film can improve electrical operation characteristics of a solar cell, it may be applied for a dielectric layer, an insulation layer, a passivation layer, etc. of various solar cells.

### BRIEF DESCRIPTION OF THE DRAWINGS

The above and other aspects, advantages and features of this disclosure will become more apparent by describing in further detail exemplary embodiments thereof with reference to the accompanying drawings, in which:

FIG. 1 is a cross-sectional view schematically showing an exemplary embodiment of a manufacturing process of an exemplary embodiment of a stacked film;

FIG. 2 is a cross-sectional view schematically showing another exemplary embodiment of the manufacturing process of another exemplary embodiment of a stacked film;

FIG. 3 is a cross-sectional view schematically showing still another exemplary embodiment of the manufacturing process of still another exemplary embodiment of a stacked film;

FIG. 4 is a cross-sectional view of an exemplary embodiment of a solar cell including an exemplary embodiment of a stacked film;

FIG. 5 is a graph showing the measurement results of an open circuit voltage of the solar cells according to Example 1 and Comparative Example 1; and

FIG. 6 is a graph showing the measurement results of an open circuit voltage of the solar cells according to Example 1 and Example 2.

### DETAILED DESCRIPTION OF THE INVENTION

The invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

All methods described herein can be performed in a suitable order unless otherwise indicated herein or otherwise clearly contradicted by context. The use of any and all examples, or exemplary language (e.g., “such as”), is intended merely to better illustrate the invention and does not pose a limitation on the scope of the invention unless otherwise claimed. No language in the specification should be construed as indicating any non-claimed element as essential to the practice of the invention as used herein.

Hereinafter, the present invention will be described in detail with reference to the accompanying drawings.

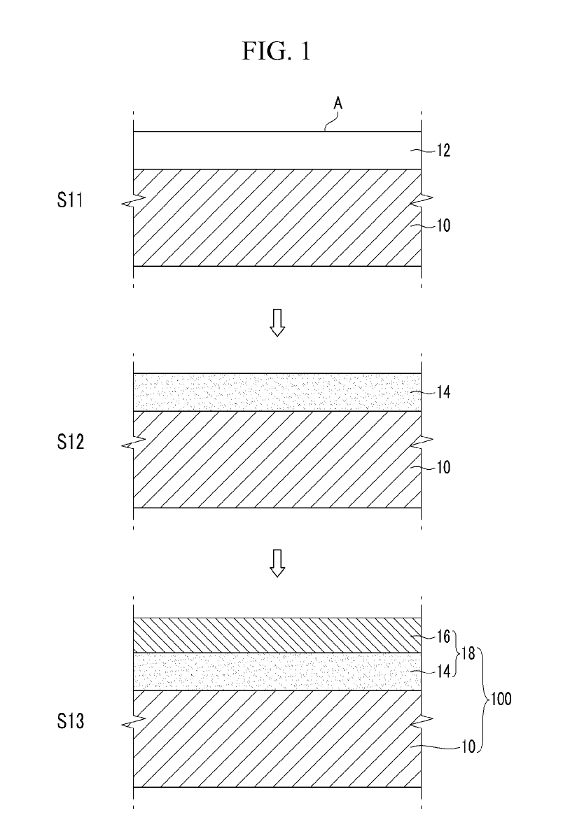

Referring to FIG. 1, an exemplary embodiment of a method of manufacturing an exemplary embodiment of a stacked film is described in detail.

FIG. 1 is a cross-sectional view schematically showing the exemplary embodiment of a manufacturing process of the exemplary embodiment of a stacked film.

First, a semiconductor substrate 10 is subjected to a radical oxidation reaction to form a radical oxide layer 12 on the surface of the semiconductor substrate (S11). Exemplary embodiments of the semiconductor substrate may include a silicon substrate, a germanium substrate, a silicon germanium substrate, a silicon-on-insulator (“SOI”) substrate, and other materials with similar characteristics, but the exemplary embodiments are not limited thereto.

In one exemplary embodiment, the radical oxidation reaction may be conducted by the reaction of a radical with an atom contained in the semiconductor substrate 10. In one exemplary embodiment, the radical may include an oxygen radical (O*), OH, hydrogen (H⁺), or other materials with similar characteristics. Exemplary embodiments include configurations wherein the radical oxidation reaction may be conducted by heat oxidation, plasma oxidation or other similar methods.

In the exemplary embodiment wherein heat oxidation is used, the process may be conducted by heating a reaction gas containing oxygen gas/hydrogen gas (O₂/H₂) or oxygen gas/deuterium gas (O₂/D₂) at a temperature from about 800° C. to about 1000° C. and under a pressure from about 0.1 Torr to about 0.5 Torr. Embodiments include configurations wherein the hydrogen gas or deuterium gas may be supplied to the semiconductor substrate 10 at a flow rate from about 2.0 slm to about 3.0 slm, and the oxygen gas may be supplied at a flow rate of from about 0.1 slm to about 0.5 slm.

In the exemplary embodiment wherein plasma oxidation is used, the process may be conducted by implanting an oxygen containing gas into inert gas plasma at a temperature from about 800° C. to about 1000° C. and under pressure of about 300 Torr or less. Embodiments include configurations wherein the inert gas may include Ar, Xe, or a mixed gas thereof, and the oxygen containing gas may include O₂, H₂O, D₂O, NO, N₂O, or other materials with similar characteristics.

Exemplary embodiments include configurations wherein the radical oxide layer 12 may be formed with a thickness of about 10 Å to about 100 Å. The radical oxide layer 12 may be formed to have a predetermined and specific depth from the initial surface of the semiconductor substrate (A in FIG. 1).

While the step of forming the radical oxide layer 12 (S11) has been described above, a process of doping an impurity of a different semiconductor type from the semiconductor substrate 10 may have been performed prior to the formation of the radical oxide layer 12 (S11). For example, in one exemplary embodiment a p-type silicon substrate may be doped with an n-type impurity. The n-type impurity may be doped by diffusing POCl₃ or H₃PO₄, or other materials with similar characteristics, at a high temperature. Thereby, the semiconductor substrate 10 may include a first type of semiconductor layer and a second type of semiconductor layer. In such an exemplary embodiment, the first type of semiconductor layer may be a p-type semiconductor layer, and the second type of semiconductor layer may be an n-type semiconductor layer.

In addition, in one exemplary embodiment a process of surface texturing the semiconductor substrate 10 may be further conducted before the step of forming the radical oxide layer (S11). In such an exemplary embodiment, the surface texturing may be carried out by a wet method using a strong acid, exemplary embodiments of which include nitric acid, hydrofluoric acid and other materials with similar characteristics, or a strong base solution, exemplary embodiments of which include sodium hydroxide or other materials with similar characteristics, or by a dry method using plasma. The surface textured semiconductor substrate 10 may have protrusions and depressions, e.g., such protrusions and depressions may have a pyramid shape, or a porous structure, e.g., such as in a honeycomb shape. The surface textured semiconductor substrate 10 may increase the surface area thereof to increase the light absorption rate and decrease reflectance thereof, thereby improving efficiency of a solar cell utilizing the same.

Exemplary embodiments include configurations wherein both the impurity doping process and the surface texturing process may be conducted, or wherein either process may be omitted, and the process sequence is not specifically limited.

In the exemplary embodiment wherein the semiconductor substrate 10 is silicon, a silicon oxide layer is formed as the radical oxide layer 12 due to a covalent bond between one silicon atom and one oxygen atom therein. However, an incomplete bond such as Si—H or Si—OH may be produced in the silicon oxide layer due to strong reactivity of the radical, and many of the incomplete bonds may exist at the interface of the semiconductor substrate 10 and the radical oxide layer 12.

Therefore, in order to compensate for such defect, the radical oxide layer 12 is annealed under a hydrogen atmosphere to convert it to a first passivation layer 14 (S12).

In one exemplary embodiment, the annealing process under a hydrogen atmosphere may be conducted for about 15 minutes to about 25 minutes, at a temperature from about 400° C. to about 1000° C. and under standard atmospheric pressure (1 ATM). Exemplary embodiments include configurations wherein the content of hydrogen gas in the hydrogen atmosphere may be in the range of about 3 volume % to about 100 volume %, and, in the embodiments wherein the hydrogen gas is not 100 volume %, the hydrogen gas may be mixed with an inert gas. If the annealing process is conducted in the above ranges, internal defects of the radical oxide layer may be sufficiently removed. In one exemplary embodiment, a purge process with an inert gas may be further conducted before conducting the annealing process, in order to remove reaction gas used in the radical oxidation process. The inert gas may include argon gas, nitrogen gas, and/or helium gas, and other materials with similar characteristics.

A clean oxidation process may be further conducted before or after conducting the annealing process, e.g., between steps S11 and S12 or after step S12.

The clean oxidation process may be conducted at a temperature of about 800° C. to about 1000° C. and under pressure from about 0.1 Torr to about 8.5 Torr, while providing a reaction gas containing oxygen gas and hydrogen chloride gas. In one exemplary embodiment, the flow ratio between the oxygen gas and the hydrogen chloride gas may be about 9.9:0.1. If the reaction gas contains about 4.0 wt % or more of hydrogen chloride gas, the semiconductor substrate 10, the radical oxide layer 12, and/or the first passivation layer 14, may be corroded. Thus, in one exemplary embodiment, the content of hydrogen chloride gas contained in the reaction gas may be controlled to about 0.8 wt % to about 3.0 wt %. In another exemplary embodiment, the content of hydrogen chloride gas contained in the reaction gas may be controlled to be about 1.0 wt % to 3.0 wt % in order to ensure clean oxidation.

A first passivation layer 14 with no defects and high purity may be provided by the annealing process under a hydrogen atmosphere and a clean oxidation process. In one exemplary embodiment, the first passivation layer 14 may be formed with a thickness of about 10 Å to about 100 Å.

The radical oxide layer 12 and the first passivation layer 14 may be substantially identically formed on the opposite surface of the semiconductor substrate 10 to function as a passivation layer. In one exemplary embodiment, the passivation layer formed on the opposite surface of the semiconductor substrate may be removed in the subsequent process of the device manufacturing process.

A second passivation layer 16 is formed on the first passivation layer 14 to prepare a stacked film 100 including a passivation layer 18 (S13).

Exemplary embodiments of the second passivation layer 16 may include a nitride layer, an oxide layer or other layer made of materials with similar characteristics. The second passivation layer may include aluminum oxide (Al₂O₃), aluminum nitride (AlN), aluminum oxynitride (AlON), silicon oxide (SiOₓ), silicon nitride (SiNₓ), silicon oxynitride (SiOₓN_{y}), silicon carbide (SiC), titanium oxide (TiOₓ), and other materials with similar characteristics.

For example, in one exemplary embodiment the second passivation layer of silicon nitride may be formed by a plasma nitriding process. The plasma nitriding process will now be explained in detail. First, in one exemplary embodiment the semiconductor substrate 10 having the first passivation layer 14 is placed in a sealed chamber, and then an inert gas is input into the chamber and about 1600 watts of microwave electrical power is applied to generate plasma. And, if nitrogen (N₂) gas is input into the chamber having plasma, nitrogen particles that gain energy via ion bombardment of the plasma bond with the silicon atoms in the passivation layer to form a silicon nitride (SiN) layer.

In one exemplary embodiment, the second passivation layer 16 may be formed with a thickness of about 700 Å to about 1000 Å. In one exemplary embodiment, the second protective layer 16 may be formed with a thickness of about 800 Å to about 950 Å. In another exemplary embodiment the second protective layer 16 may be formed with a thickness of about 850 Å to about 900 Å.

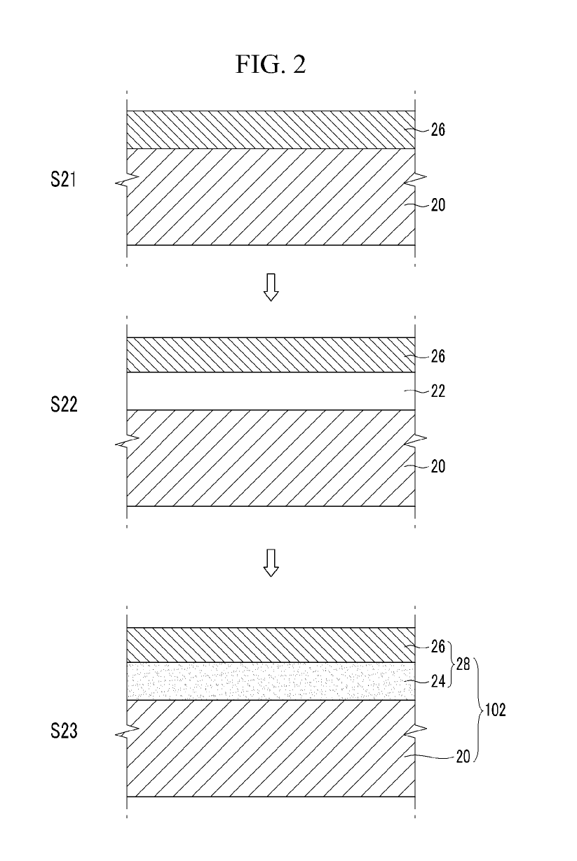

FIG. 2 is a cross-sectional view schematically showing another exemplary embodiment of the manufacturing process of an exemplary embodiment of a stacked film.

As shown in FIG. 2, a second passivation layer 26 is formed on a semiconductor substrate 20 (S21). The process of forming the second passivation layer 26 is the same as that described in the process of forming the second passivation layer 16 (S13) in the exemplary embodiment illustrated in FIG. 1. In one exemplary embodiment, the second passivation layer 26 may be a nitride layer or an oxide layer. Exemplary embodiments of the second passivation layer may include aluminum oxide (Al₂O₃) or aluminum nitride (AlN), aluminum oxynitride (AlON), silicon oxide (SiOₓ), silicon nitride (SiNₓ), silicon oxynitride (SiOₓN_{y}), silicon carbide (SiC), titanium oxide (TiOₓ), and other materials having similar characteristics.

Then, the semiconductor substrate 20 having the second passivation layer 26 disposed thereon is subjected to a radical oxidation reaction to form a radical oxide layer 22 under the second passivation layer 26 (S22). In one exemplary embodiment the process of forming the radical oxide layer 22 may be substantially the same as described in the process of forming the radical oxide layer 12 (S11) in the exemplary embodiment illustrated in FIG. 1.

Then, the radical oxide layer 22 is annealed under a hydrogen atmosphere, and then a clean oxidation process is conducted to form a first passivation layer 24, thereby preparing an exemplary embodiment of a stacked film 102 including a passivation layer 28 (S23). In one exemplary embodiment, the process of forming the first passivation layer 24 is substantially the same as described in the process of forming the first passivation layer 14 (S12) in the exemplary embodiment of FIG. 1.

In one exemplary embodiment, a process of doping an impurity of a different semiconductor type from the semiconductor substrate 20 may be further conducted before the step of forming the second passivation layer 26 (S21). For example, in one exemplary embodiment a p-type silicon substrate may be doped with an n-type impurity. Exemplary embodiments of the n-type impurity may be doped by diffusing POCl₃ or H₃PO₄, or other materials with similar characteristics, at a high temperature. Thereby, the semiconductor substrate 10 may include a first type of semiconductor layer and a second type of semiconductor layer. In such an exemplary embodiment, the first type of semiconductor layer may be a p-type semiconductor layer, and the second type of semiconductor layer may be an n-type semiconductor layer.

In one exemplary embodiment, a process of surface texturing the semiconductor substrate 20 may be further conducted before the step of forming the second passivation layer 26 (S21), a. In one exemplary embodiment, the surface texturing may be carried out by a wet method using a strong acid, exemplary embodiments of which include nitric acid and hydrofluoric acid, or a strong base solution, an exemplary embodiment of which includes sodium hydroxide, or by a dry method using plasma. The surface textured semiconductor substrate 20 may have protrusions and depressions, e.g., such protrusions and depressions may have a pyramid shape, or a porous structure such as a honeycomb shape. The surface textured semiconductor substrate 20 may increase the surface area thereof to increase the light absorption rate and decrease reflectance thereof thereby improving efficiency of a solar cell including the same.

Exemplary embodiments include configurations wherein both the impurity doping process and the surface texturing process may be conducted, or either process may be omitted, and the process sequence is not specifically limited.

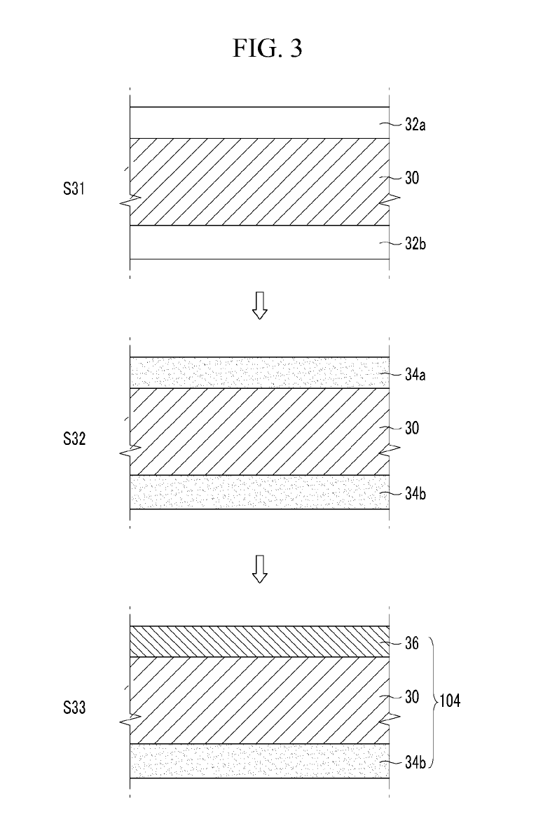

FIG. 3 is a cross-sectional view showing another exemplary embodiment of the manufacturing process of another embodiment of a stacked film.

As shown in FIG. 3, a semiconductor substrate 30 is subjected to a radical oxidation reaction to form radical oxide layers 32a and 32b on the surface of the semiconductor substrate 30 (S31). The process of forming the radical oxide layers 32a and 32b is substantially the same as described in the process of forming the radical oxide layer 12 (S11) in the exemplary embodiment of FIG. 1.

The radical oxide layers 32a and 32b are annealed under a hydrogen atmosphere to convert the radical oxide layers 32a and 32b to first passivation layers 34a and 34b (S32). In one exemplary embodiment, the annealing process may be conducted for about 30 minutes or more. In another exemplary embodiment, the annealing process may be conducted for about 1 hour or more. In another exemplary embodiment, the annealing process may be conducted for about 1 hour to about 3 hours. In one exemplary embodiment, the content of hydrogen gas may be in the range of about 3 volume % to about 100 volume %. If the annealing process is conducted in the above range, internal defects of the radical oxide layer 32a or 32b may be sufficiently removed. In the present exemplary embodiment, the process of forming the first passivation layers 34a and 34b is substantially the same as described in the process of forming the first passivation layer 14 (S12) in the exemplary embodiment of FIG. 1, except for the annealing process.

A clean oxidation process may be further conducted before or after conducting the annealing process.

In the present exemplary embodiment, the first passivation layer 34a formed on the surface of the semiconductor substrate 30 is removed, and then a second passivation layer 36 is formed on the semiconductor substrate 30 to prepare a stacked film 104 (S33). In the present exemplary embodiment, the process of forming the second passivation layer 36 is substantially the same as described in the process of forming the second passivation layer 16 (S13) in FIG. 1. In one exemplary embodiment, the second passivation layer 36 may be a nitride layer, an oxide layer or other layer made from materials with similar characteristics. In one exemplary embodiment, the second passivation layer may include aluminum oxide (Al₂O₃), aluminum nitride (AlN), aluminum oxynitride (AlON), silicon oxide (SiOₓ), silicon nitride (SiNₓ), silicon oxynitride (SiOₓN_{y}), silicon carbide (SiC), titanium oxide (TiOₓ), or other materials with similar characteristics.

Exemplary embodiments also include configurations wherein the first passivation layer 34b may also be removed in a device manufacturing process.

Exemplary embodiments include configurations wherein a process of doping an impurity of a different semiconductor type from the semiconductor substrate 30 may be further conducted before the step of forming the radical oxide layer (S31). For example, in one exemplary embodiment a p-type silicon substrate may be doped with an n-type impurity. In one exemplary embodiment, the n-type impurity may be doped by diffusing POCl₃ or H₃PO₄, etc., at a high temperature. Thereby, the semiconductor substrate 30 may include a first type of semiconductor layer and a second type of semiconductor layer. The first type of semiconductor layer may be a p-type semiconductor layer, and the second type of semiconductor layer may be an n-type semiconductor layer.

A process of surface texturing the semiconductor substrate 30 may be further conducted before the step of forming the radical oxide layer (S31). Exemplary embodiments include configurations wherein the surface texturing may be carried out by a wet method using a strong acid, exemplary embodiments of which include nitric acid and hydrofluoric acid, or a strong base solution, an exemplary embodiment of which includes sodium hydroxide, or by a dry method using plasma. Exemplary embodiments include configurations wherein the surface textured semiconductor substrate 30 may have protrusions and depressions, e.g., a pyramid shape, or a porous structure, e.g., in a honeycomb shape. The surface textured semiconductor substrate 30 may increase the surface area thereof to increase the light absorption rate and decrease reflectance thereof, thereby improving efficiency of a solar cell utilizing the same.

Exemplary embodiments include configurations wherein both the impurity doping process and the surface texturing process may be conducted, or exemplary embodiments wherein one or both processes are omitted, and the process sequence is not specifically limited.

A process of doping an impurity of a different semiconductor type from the semiconductor substrate 30 may be further conducted after removing the first passivation layer 34a and before forming the second passivation layer 36 on the surface of the semiconductor substrate 30. In one exemplary embodiment, the impurity doping process is substantially the same as described above.

The above-prepared stacked films 100, 102, and 104 may be used as a dielectric layer, an insulation layer, a passivation layer, or various other components of a solar cell.

According to the above described exemplary embodiments, the stacked film includes a semiconductor substrate including a first type of semiconductor layer and a second type of semiconductor layer, and a first passivation layer and a second passivation layer on the semiconductor substrate or a second passivation layer on the semiconductor substrate. A first electrode electrically connected to the first type of impurity containing semiconductor layer of the stacked film and a second electrode electrically connected to the second type of impurity containing semiconductor layer may be formed to prepare an exemplary embodiment of a solar cell.

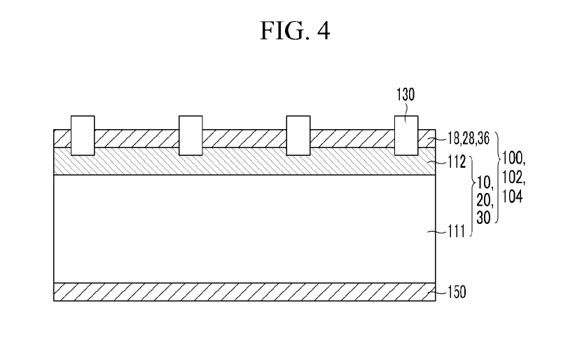

FIG. 4 is a cross-sectional view of a solar cell including any one of the exemplary embodiments of stacked films 100, 102, and 104.

For better understanding and ease of description, an up/down position relationship is described corresponding to the semiconductor substrates 10, 20, and 30, but the present invention is not limited thereto and one of ordinary skill in the art would recognize that the same structure oriented in a different manner may have the up/down descriptors rearranged. As described herein, a solar energy receiving side is referred to as a front side of the solar cell, and the opposite side of the front side is referred to as a rear side of the solar cell.

Referring to FIG. 4, semiconductor substrates 10, 20, and 30 include a lower semiconductor layer 111 and an upper semiconductor layer 112. The lower semiconductor layer 111 is positioned at the rear side of the solar cell, and the upper semiconductor layer 112 is positioned at the front side of the solar cell.

Passivation layers 18, 28 and 36 may be positioned on the semiconductor substrates 10, 20, and 30.

The passivation layers 18, 28 and 36 may function as an anti-reflective coating (“ARC”) for decreasing the light reflection rate at the surface of a solar cell and increasing selectivity of a specific wavelength region, e.g., the ARC may narrow a wavelength range passing therethrough, and simultaneously improve the contact characteristic with silicon existing at the surface of the semiconductor substrates 10, 20, and 30, thereby increasing efficiency of a solar cell.

A plurality of front electrodes 130 are formed on the surface of the passivation layers 18, 28, and 36. The front electrodes 130 extend substantially parallel to one direction of the substrate, and penetrate through the passivation layers 18, 28, and 36 to contact the upper semiconductor layer 112. In one exemplary embodiment, the front electrode 130 may be made of a low resistance metal such as silver (Ag), or other materials with similar characteristics., and may be designed as a grid pattern considering shadowing loss and sheet resistance.

In one exemplary embodiment, a front electrode bus bar (not shown) is formed on the front electrode 130. The front electrode bus bar is to connect neighboring solar cells when assembling a plurality of solar cells, e.g., when manufacturing a solar panel.

In one exemplary embodiment, a dielectric layer (not shown) may be formed on the rear side of the semiconductor substrates 10, 20, and 30. The dielectric layer may include silicon oxide (SiO₂), silicon nitride (SiNₓ), aluminum oxide (Al₂O₃) and other materials with similar characteristics, and it may prevent charge recombination and leakage current to increase efficiency of a solar cell.

A rear electrode 150 is formed on the other surface of the semiconductor substrates 10, 20, and 30.

In one exemplary embodiment, the rear electrode 150 may be made of an opaque metal such as aluminum (Al), and it may be formed on the front side of a dielectric layer to reflect light passing the semiconductor substrates 10, 20, and 30 back into the semiconductor substrate, thereby preventing light leakage to increase efficiency.

The following examples illustrate this disclosure in more detail. However, it is understood that this disclosure is not limited by these examples.

### EXAMPLE 1

### Manufacture of a Solar Cell

In the present example according to an exemplary embodiment, POCl₃ is diffused into a pyramidally surface textured silicon wafer to dope the wafer with an n-type impurity

A gas containing oxygen gas/hydrogen gas (O₂/H₂, 10/1 volume ratio) is flowed at a temperature of about 900° C. and under pressure of about 0.33 Torr, and reacted for about 7.5 hours to form an oxide layer. Then, the oxide layer is heat treated 1-5 times at about 400° C. while supplying a reaction gas containing about 3 volume % of hydrogen. A nitride layer (anti-reflection coating) is formed on the oxide layer to form a stacked film. A silver electrode (front electrode) is formed on the surface of the stacked film, and an aluminum electrode (rear electrode) is formed on the other surface of the stacked film to prepare an exemplary embodiment of a solar cell.

### COMPARATIVE EXAMPLE 1

A solar cell is prepared by the same method as in Example 1, except that the heat treatment atmosphere is changed to nitrogen (100 volume %).

<Control 1>

A solar cell is prepared by the same method as in Example 1, except that the heat treatment process is not conducted.

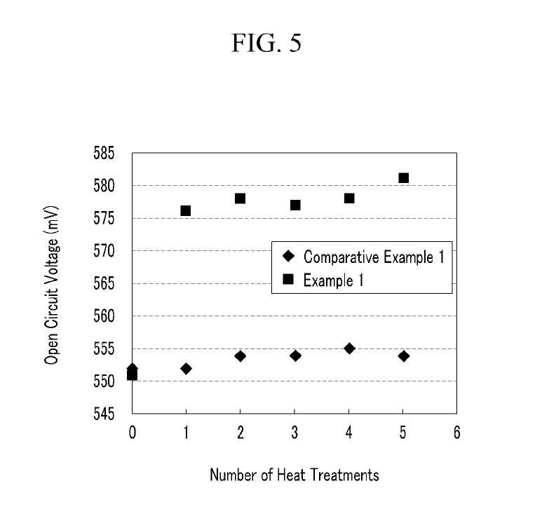

An open-circuit voltage (“Voc”) of the solar cells of Example 1 and Comparative Example 1 are measured according to the number of heat treatments and described in the following Table 1 and FIG. 5. Voc of the Control 1 solar cell is 551 mV.

TABLE 1

| | | Comparative |
|---|---|---|
| Number of heat | Example 1 | Example 1 |
| treatments | (Voc (mV)) | (Voc (mV)) |
| 1 | 576 | 552 |
| 2 | 578 | 554 |
| 3 | 577 | 554 |
| 4 | 578 | 555 |
| 5 | 581 | 554 |

As shown in the Table 1 and FIG. 5, it can be seen that Voc of the exemplary embodiment of a solar cell according Example 1 is higher than that of the solar cell of Comparative Example 1.

### EXAMPLE 2

### Manufacture of Solar Cell

A solar cell is manufactured by substantially the same method as in Example 1, except that a clean oxidation process is further conducted after conducting the heat treatment process 1 to 5 times.

The clean oxidation process is conducted while supplying a reaction gas containing oxygen gas and hydrogen chloride gas (100/1 weight ratio) at a temperature of about 950° C. and under pressure of about 7.5 Torr for about 125 seconds.

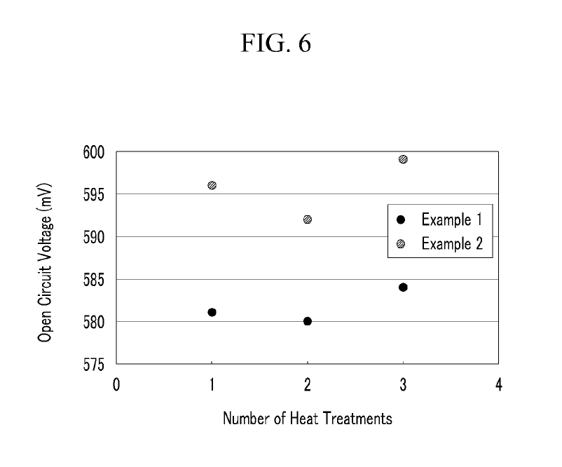

Vocs of the solar cells according to Examples 1 and 2 are measured and are shown in FIG. 6. As shown in FIG. 6, it can be seen that Voc of Example 2 wherein a clean oxidation process is conducted is improved compared to Example 1. While there is some small discrepancy between the measurements of Example 1 illustrated in FIGS. 5 and 6, such discrepancies are due to minor statistical aberrations in the second set of measurements that results in slightly different measurements.

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A method of manufacturing a stacked film, the method comprising:
subjecting a semiconductor substrate to a radical oxidation reaction to form a radical oxide layer on a surface of the semiconductor substrate;
annealing the radical oxide layer in a hydrogen atmosphere to convert the radical oxide layer to a first passivation layer; and
disposing a second passivation layer on the first passivation layer.

2. The method of claim 1, wherein at least one of a doping process wherein an impurity of a different semiconductor type from the semiconductor substrate is doped in the semiconductor substrate and a process of surface texturing the semiconductor substrate is conducted prior to forming the radical oxide layer.

3. The method of claim 2, wherein the semiconductor substrate is a p-type semiconductor and the impurity is an n-type semiconductor.

4. The method of claim 1, wherein the radical oxidation reaction is performed by at least one of heat oxidation and plasma oxidation.

5. The method of claim 1, wherein the annealing process is conducted from about 15 minutes to about 25 minutes.

6. The method of claim 1, wherein the annealing process is conducted at a temperature from about 400° C. to about 1000° C.

7. The method of claim 1, wherein a clean oxidation process is further conducted before or after annealing the radical oxide layer.

8. The method of claim 7, wherein the clean oxidation process is conducted while supplying a reaction gas atmosphere containing oxygen gas and hydrogen chloride gas.

9. A method of manufacturing a stacked film, the method comprising:
disposing a second passivation layer on a semiconductor substrate;
subjecting the semiconductor substrate on which the second passivation layer is disposed to a radical oxidation reaction to form a radical oxide layer between the second passivation layer and the semiconductor substrate; and
annealing the radical oxidation layer in a hydrogen atmosphere to convert the radical oxidation layer to a first passivation layer.

10. The method of claim 9, wherein at least one of a doping process wherein an impurity of a different semiconductor type from the semiconductor substrate is doped in the semiconductor substrate and a process of surface texturing the semiconductor substrate is conducted prior to forming the radical oxide layer.

11. The method of claim 10, wherein the semiconductor substrate is a p-type semiconductor, and the impurity is an n-type semiconductor.

12. The method of claim 9, wherein the radical oxidation reaction is performed by at least one of heat oxidation and plasma oxidation.

13. The method of claim 9, wherein the annealing process is conducted for about 15 minutes to about 25 minutes.

14. The method of claim 9, wherein the annealing process is conducted at a temperature from about 400° C. to about 1000° C.

15. The method of claim 9, wherein a clean oxidation process is performed before or after annealing the radical oxidation layer.

16. The method of claim 15, wherein the clean oxidation process is conducted while supplying a reaction gas atmosphere containing oxygen gas and hydrogen chloride gas.

17. A method of manufacturing a stacked film, the method comprising:
subjecting a semiconductor substrate to a radical oxidation reaction to form a radical oxide layer on a surface of the semiconductor substrate;
annealing the radical oxidation layer in a hydrogen atmosphere to convert it to a first passivation layer; and
removing the first passivation layer formed on the surface of the semiconductor substrate; and
disposing a second passivation layer on the surface of the semiconductor substrate.

18. The method of claim 17, wherein at least one of a doping process wherein an impurity of a different semiconductor type from the semiconductor substrate is doped in the semiconductor substrate and a process of surface texturing the semiconductor substrate is conducted prior to the step of forming the radical oxide layer.

19. The method of claim 17, wherein the semiconductor substrate is a p-type semiconductor, and the impurity is an n-type semiconductor.

20. The method of claim 17, wherein the radical oxidation reaction is conducted by at least one of heat oxidation and plasma oxidation.

21. The method of claim 17, wherein a doping process wherein an impurity of a different semiconductor type from the semiconductor substrate is conducted prior to forming the second passivation layer on the surface of the semiconductor substrate from which the passivation layer is removed.

22. The method of claim 17, wherein the annealing process is conducted for at least about 30 minutes.

23. The method of claim 17, wherein the annealing process is conducted at a temperature from about 400° C. to about 1000° C.

24. The method of claim 17, wherein a clean oxidation process is conducted before or after annealing the radical oxidation layer.

25. The method of claim 24, wherein the clean oxidation process is conducted while supplying a reaction gas atmosphere containing oxygen gas and hydrogen chloride gas.

26. A method of manufacturing a solar cell, the method comprising:
providing a semiconductor substrate comprising a first semiconductor layer including a first type of semiconductor material and a second semiconductor layer including a second type of semiconductor layer;
disposing a stacked film on the semiconductor substrate; and
disposing a first electrode electrically connected with the first semiconductor layer, and a second electrode electrically connected with the second semiconductor layer,
wherein the stacked film is formed by the method comprising:
subjecting a semiconductor substrate to a radical oxidation reaction to form a radical oxide layer on a surface of the semiconductor substrate,
annealing the radical oxide layer in a hydrogen atmosphere to convert the radical oxide layer to a first passivation layer, and
disposing a second passivation layer on the first passivation layer.

27. The method of claim 26, wherein the first semiconductor layer is a p-type semiconductor layer, and the second semiconductor layer is an n-type semiconductor layer.

28. A method of manufacturing a solar cell, the method comprising:
providing a semiconductor substrate comprising a first semiconductor layer including a first type of semiconductor material and a second semiconductor layer including a second type of semiconductor material;
disposing a stacked film on the semiconductor substrate; and
disposing a first electrode electrically connected with the first semiconductor layer, and a second electrode electrically connected with the second semiconductor layer,
wherein the stacked film is formed by the method comprising:
disposing a second passivation layer on the semiconductor substrate;
subjecting the semiconductor substrate on which the second passivation layer is formed to a radical oxidation reaction to form a radical oxide layer between the second passivation layer and the semiconductor substrate; and
annealing the radical oxidation layer in a hydrogen atmosphere to convert the radical oxidation layer to a first passivation layer.

29. The method of claim 28, wherein the first semiconductor layer is a p-type semiconductor layer, and the second semiconductor layer is an n-type semiconductor layer.

30. A method of manufacturing a solar cell, the method comprising:
providing a semiconductor substrate comprising a first semiconductor layer including a first type of semiconducting material and a second semiconductor layer including a second type of semiconducting material;
disposing a stacked film on the semiconductor substrate; and
disposing a first electrode electrically connected with the first semiconductor layer, and a second electrode electrically connected with the second semiconductor layer,
wherein the stacked film is disposed by the method comprising:
subjecting the semiconductor substrate to a radical oxidation reaction to form a radical oxide layer on a surface of the semiconductor substrate;
annealing the radical oxidation layer in a hydrogen atmosphere to convert the radical oxidation layer to a first passivation layer; and
removing the first passivation layer formed on the surface of the semiconductor substrate; and
forming a second passivation layer on the surface of the semiconductor substrate.

31. The method of claim 30, wherein the first semiconductor layer is a p-type semiconductor layer, and the second semiconductor layer is an n-type semiconductor layer.
